(19) United States
(12) Patent Application Publication
(10) Pub. No.: US 2016/0020366 A1
(43) Pub. Date: Jan. 21, 2016

(54) METHOD OF MANUFACTURING LIGHT-EMITTING DEVICE PACKAGE

(71) Applicant: SAMSUNG ELECTRONICS CO., LTD., Suwon-si (KR)

(72) Inventors: Sun-jun HWANG, Suwon-si (KR); Won-soo JI, Hwaseong-si (KR); Do-hyuk KIM, Hwaseong-si (KR)

(21) Appl. No.: 14/708,047

(22) Filed: May 8, 2015

(30) Foreign Application Priority Data
Jul. 21, 2014 (KR) 10-2014-0092158

(51) Int. Cl. H01L 33/50; H01L 21/66; H01L 33/58

(52) U.S. Cl. CPC H01L 33/505; H01L 33/58; H01L 22/10; H01L 2933/0041; H01L 2933/0058

(57) ABSTRACT

A method of manufacturing a light-emitting device package may include steps of preparing a light-emitting device package; holding the light-emitting device package on an inspection table; reflecting, by a reflection member, leaking blue light emitted by the light-emitting device package; capturing, by using a photographing unit, the light emitted by the light-emitting device package and the leaking blue light and generating an optical image; detecting, by a controller, the blue light from the optical image; determining a presence or absence of a defect of the light-emitting device package according to the detected blue light; and displaying the presence or absence of the defect of the light-emitting device package on a display unit.

### CROSS-REFERENCE TO RELATED APPLICATION

This application claims the benefit of Korean Patent Application No. 10-2014-0092158, filed on Jul. 21, 2014, in the Korean Intellectual Property Office, the disclosure of which is incorporated herein in its entirety by reference.

### BACKGROUND

The present disclosure relates to a method of manufacturing a light-emitting device package, and more particularly, to a method of manufacturing a light-emitting device package, which includes inspecting a defect of the light-emitting device package.

A light-emitting device package may include a light-emitting device, a phosphor layer covering the light-emitting device, and a lens unit covering the light-emitting device and the phosphor layer. In the process of manufacturing the light-emitting device package, foreign substances may be adsorbed on the surface of the light-emitting device package, and a shape failure of a phosphor layer or an etching failure may occur. Therefore, in the process of manufacturing the light-emitting device package, a state of the light-emitting device package is checked by inspecting the appearance and performance of the light-emitting device package prior to a release of a product. An apparatus for inspecting the defect of the light-emitting device package is configured to inspect the appearance of a small light-emitting device package and the defect of the light-emitting characteristics. Such an apparatus is increasingly required because the defect may be prevented before the light-emitting device package is mounted on an expensive precision electronic product.

### SUMMARY OF THE INVENTION

The present disclosure provides a method of manufacturing a light-emitting device package, which includes inspecting a defect of the light-emitting device package by detecting blue light leaking out from a light-emitting device due to an arrangement failure or a shape failure of a phosphor layer formed on the light-emitting device.

According to an aspect of the present disclosure, there is provided a method of manufacturing a light-emitting device package, the method including: preparing a light-emitting device package; holding the light-emitting device package on an inspection table; reflecting, by using a reflection member, leaking blue light emitted by the light-emitting device package; capturing, by using a photographing unit, the light emitted by the light-emitting device package and the leaking blue light and generating an optical image; detecting, by using a controller, the blue light from the optical image; determining a presence or absence of a defect of the light-emitting device package according to a ratio of the detected blue light; and displaying the presence or absence of the defect of the light-emitting device package on a display unit.

The preparing of the light-emitting device package may include: forming a light-emitting device on a substrate; forming a phosphor layer that covers the light-emitting device; and forming a lens unit that covers a top surface of the substrate, the light-emitting device, and the phosphor layer.

The light-emitting device may generate blue light, and the generated blue light may be emitted as white light through the phosphor layer.

The inspection table may include: a holding table on which the light-emitting device package is held; and a coupling groove portion coupled to one side of a top surface of the light-emitting device package to fix the light-emitting device package.

The reflection member may be formed to be inclined at a predetermined angle with respect to a top surface of the inspection table.

The reflection member may be made of a coated alloy capable of reflecting the blue light leaking out from the light-emitting device package.

The reflection member may be disposed adjacent to each side of the light-emitting device package.

The controller may selectively detect blue light having a wavelength of about 400 nm to about 500 nm in the reflected light.

The light-emitting device package may include a light-emitting region that emits white light, and the controller may calculate a ratio of a region where blue light is recorded with respect to a region of the entire optical image, except for the light-emitting region, and execute an algorithm of determining a presence or absence of a defect according to a calculation result.

The light-emitting device package may be determined as defective when the ratio of the region where the blue light is recorded with respect to a region of the entire optical image, except for a region where white light emitted from the light-emitting region is recorded, is 7% or more.

The ratio may be displayed on the display unit.

According to another aspect of the present disclosure, there is provided a method of manufacturing a light-emitting device package, the method including: preparing a light-emitting device package by forming a phosphor layer on a light-emitting device emitting blue light, wherein the phosphor layer performs conversion to emit white light; and determining a presence or absence of a defect of the light-emitting device package, wherein the determining of the presence or absence of the defect of the light-emitting device package may include: forming a reflection member surrounding each side of the light-emitting device package; detecting, by using a controller, leaking blue light from light emitted by the light-emitting device package; calculating a ratio of the leaking blue light with respect to the entire reflected light; and determining, by using the controller, the presence or absence of the defect of the light-emitting device package according to the ratio of the leaking blue light with respect to the entire reflected light.

The determining of the presence or absence of the defect of the light-emitting device package further may include displaying the ratio of the leaking blue light on a display unit.

The determining of the presence or absence of the defect of the light-emitting device package may further include: holding the light-emitting device package on an inspection table; and fixing the light-emitting device package by coupling one side of a top surface of the light-emitting device package.

The determining of the presence or absence of the defect of the light-emitting device package may further include: capturing, by using a photographing unit, the reflected light and generating an image; and transferring, by using the controller, the image.

According to another aspect of the present disclosure, a method of inspecting a defect of a light-emitting device package may include steps of mounting a light-emitting device package on an inspection table; converting light emitted by the light-emitting device package and blue light leaked from the light-emitting package to an image; presetting a peripheral region of the image; determining a ratio of a region of the image, which is converted by the blue light, with respect to the preset peripheral region of the image; and determining a presence or absence of a defect of the light-emitting device package in accordance with whether the determined ratio is equal to and greater than a predetermined ratio.

The method may further include a step of reflecting the blue light leaked from the light-emitting package to a photographing unit used to capture the image.

The method may further include a step of displaying the presence or absence of the defect of the light-emitting device package on a display unit.

The predetermined ratio may be equal to 7%.

The preset peripheral region may not include a center region of the image which is converted by the light emitted by the light-emitting device package.

### BRIEF DESCRIPTION OF THE DRAWINGS

Exemplary embodiments of the present invention will be more clearly understood from the following detailed description taken in conjunction with the accompanying drawings in which:

FIG. 1 is a configuration diagram for describing a method of manufacturing a light-emitting device package, according to an embodiment of the present invention;

FIG. 2 is a flowchart of the method of manufacturing the light-emitting device package, according to an embodiment of the present invention;

FIG. 3 is a conceptual diagram of a method of manufacturing a light-emitting device package, according to an embodiment of the present invention;

FIG. 4 is a cross-sectional view of a light-emitting device package corresponding to a preparing operation in the method of manufacturing the light-emitting device package, according to an embodiment of the present invention;

FIGS. 5A and 5B are cross-sectional views of a light-emitting device of a light-emitting device package corresponding to the preparing operation in the method of manufacturing the light-emitting device package, according to an embodiment of the present invention;

FIG. 6 illustrates a CIE 1931 coordinate system for describing various examples of a wavelength conversion material adoptable to a phosphor layer of a light-emitting device package corresponding to the preparing operation in the method of manufacturing the light-emitting device package, according to an embodiment of the present invention;

FIG. 7 is a perspective view of an inspection apparatus and a light-emitting device package corresponding to the inspecting operation in the method of manufacturing the light-emitting device package, according to an embodiment of the present invention;

FIG. 8A is a plan view of the inspection apparatus and the light-emitting device package corresponding to the inspecting operation in the method of manufacturing the light-emitting device package, according to an embodiment of the inventive concept, and FIG. 8B is a cross-sectional view of the inspection apparatus and the light-emitting device package;

FIGS. 9A to 9C are cross-sectional views for describing the cause of defects of light-emitting device packages in the method of manufacturing the light-emitting device package, according to an embodiment of the present invention;

FIG. 10 is a diagram of an image displayed on a display unit in a defect determining operation in the method of manufacturing the light-emitting device package, according to an embodiment of the present invention;

FIG. 11 illustrates a coordinate system of light-emitting wavelengths of a light-emitting device so as to describe a defect determining operation of a controller in the method of manufacturing the light-emitting device package, according to an embodiment of the present invention;

FIG. 12 illustrates an exemplary image for describing the defect determining operation of the controller in the method of manufacturing the light-emitting device package, according to an embodiment of the present invention;

FIG. 13 is a conceptual diagram of an example in which the light-emitting device package manufactured by the manufacturing method according to the embodiment of the present invention is applied to an illumination system; and

FIG. 14 is a conceptual diagram of an example in which the light-emitting device package manufactured by the manufacturing method according to the embodiment of the present invention is applied to a head lamp.

The patent or application file contains at least one drawing executed in color. Copies of this patent or patent application publication with color drawing(s) will be provided by the Office upon request and payment of the necessary fee.

### DETAILED DESCRIPTION OF THE INVENTION

Hereinafter, embodiments of the inventive concept will be described with reference to the accompanying drawings. The inventive concept may, however, be embodied in many different forms and should not be construed as being limited to the embodiments set forth herein; rather, these embodiments are provided so that this disclosure will be thorough and complete, and will fully convey the inventive concept to those of ordinary skill in the art. It should be understood, however, that there is no intent to limit the inventive concept to the particular forms disclosed, but on the contrary, the inventive concept is to cover all modifications, equivalents, and alternatives falling within the spirit and scope of the inventive concept. Like reference numerals denote like elements throughout the specification and drawings. In the drawings, the dimensions of structures are exaggerated for clarity of the inventive concept.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms “first”, “second”, “third”, etc. may be used herein to describe various elements, these elements should not be limited by these terms. These terms are only used to distinguish one element from another. For example, a first element may be referred to as a second element, and similarly, a second element may be referred to as a first element without departing from the scope of protection of the inventive concept.

As used herein, the singular forms “a”, “an”, and “the” are intended to include the plural forms as well, unless the context clearly indicates otherwise. It will be understood that terms such as “comprise”, “include”, and “have”, when used herein, specify the presence of stated features, integers, steps, operations, elements, components, or combinations thereof, but do not preclude the presence or addition of one or more other features, integers, steps, operations, elements, components, or combinations thereof.

Unless otherwise defined, all terms used herein have the same meaning as commonly understood by one of ordinary skill in the art to which exemplary embodiments belong.

Hereinafter, exemplary embodiments will be described in detail with reference to the accompanying drawings.

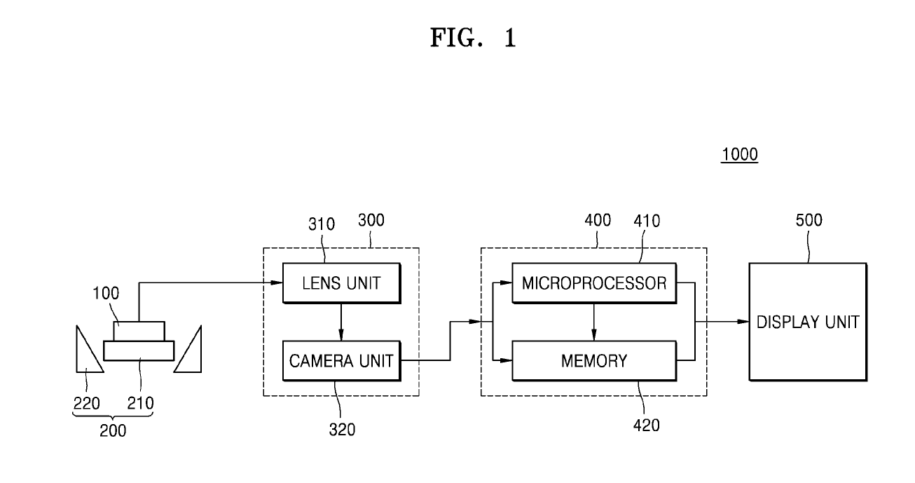

FIG. 1 is a configuration diagram 1000 for describing a method of manufacturing a light-emitting device package, according to an embodiment of the present invention.

Referring to FIG. 1, the configuration diagram 1000 may include a light-emitting device package 100, an inspection apparatus 200 that inspects the light-emitting device package 100, a photographing unit 300 that captures light emitted by the light-emitting device package 100, a controller 400 that receives an image captured by the photographing unit 300 and determines a presence or absence of a defect of the light-emitting device package 100, and a display unit 500 that displays a defect presence/absence signal received from the controller 400.

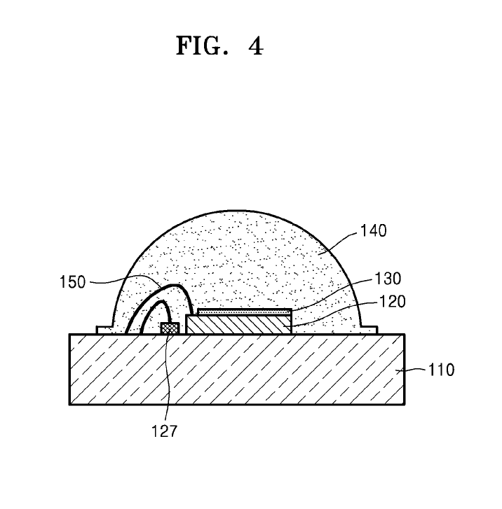

The light-emitting device package 100 may include a light-emitting device 120 (see FIG. 4), a phosphor layer 130 (see FIG. 4), and a lens unit 140 (see FIG. 4). The light-emitting device 120 of the light-emitting device package 100 may emit blue light, and the emitted blue light may be converted to white light, green light, or red light through the phosphor layer 130. The light-emitting device package 100 will be described below in detail with reference to FIGS. 4, 5A, 5B, and 7.

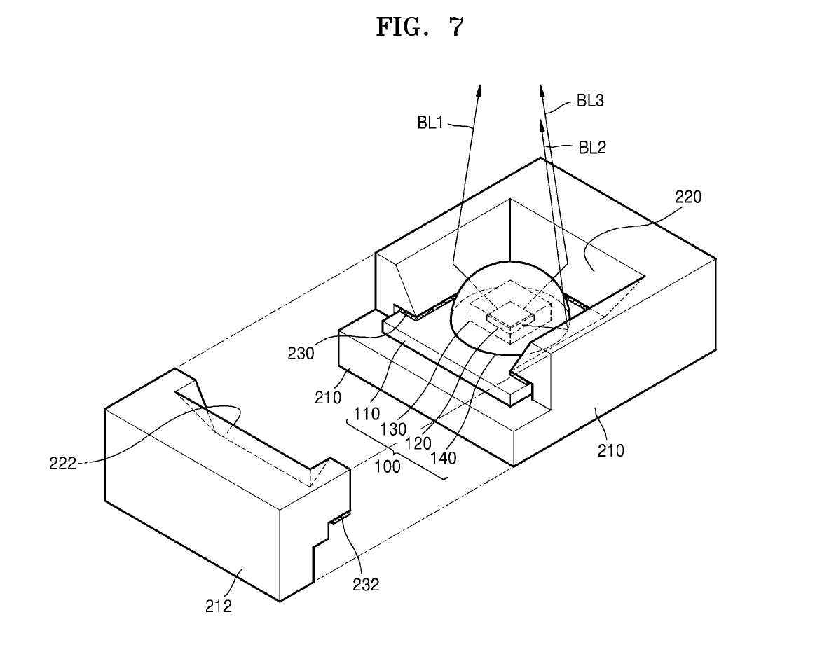

The inspection apparatus 200 may include a holder 210 and a reflection member 220. The holder 210 may be made of thoron or Vespel. The light-emitting device package 100 may be held on the holder 210 and be inserted into and fixed to coupling groove portions 230 and 232 (see FIG. 7) formed on one side of the holder 210. The coupling groove portions 230 and 232 may have a certain depth and a certain height so that a part of an edge of a substrate 110 of the light-emitting device package 100 is inserted and fixed thereto. According to an exemplary embodiment of the present invention, the height of the coupling groove portions 230 and 232 may be in the range of about 0.5 mm to about 2.0 mm, considering the thickness of the substrate 110.

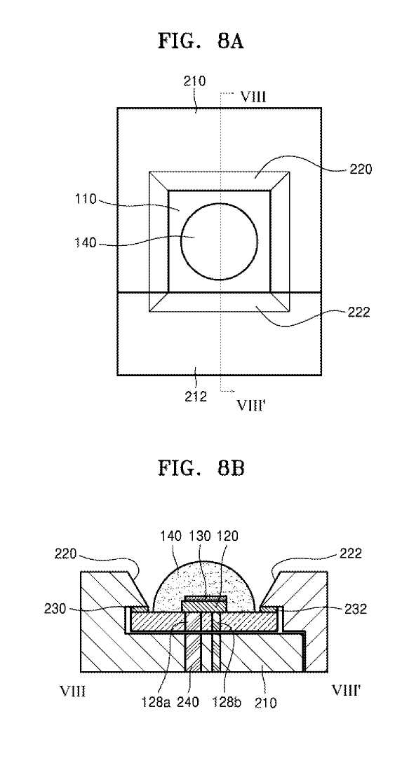

The reflection member 220 may be formed adjacent to a side of the light-emitting device package 100. The reflection member 220 may reflect blue light leaking out from the light-emitting device package 100. According to an exemplary embodiment of the present invention, the reflection member 220 may be made of a different material from that of the holder 210 and be used after installation and assembling on the holder 210. The material of the reflection member 220 may be STD 11. In order to reflect light emitted from the light-emitting device, the surface of the reflection member 220 may be lapped and the surface roughness (Rₘₐₓ) of the reflection member 220 may be 0.1 S or less. According to an exemplary embodiment of the present invention, the surface roughness (Rₘₐₓ) of the reflection member 220 may be 0.05 S or less. A surface heat treatment hardness of the reflection member 220 may be equal to or greater than HRC 58 to 60, and a tilt angle of the reflection member 220 from the surface of the holder 210 may be in the range of about 30° to about 60°. According to an exemplary embodiment of the present invention, the tilt angle of the reflection member 220 may be about 45°. The holder 210 and the reflection member 220 will be described below in detail with reference to FIGS. 7, 8A, and 8B.

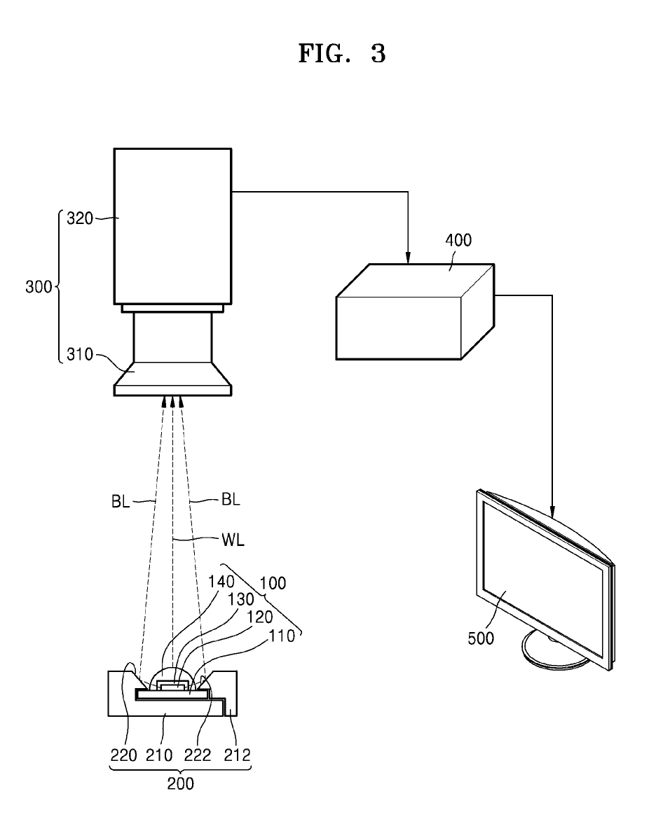

The photographing unit 300 may include a lens unit 310 and a camera unit 320. The lens unit 310 may capture white light emitted by the light-emitting device package 100 and blue light reflected by the reflection member 220. The lens unit 310 may include an optical lens. The camera unit 320 may image the white light and the blue light captured by the lens unit 310. The camera unit 320 may include an image sensor. The photographing unit 300 will be described below in detail with reference to FIG. 3.

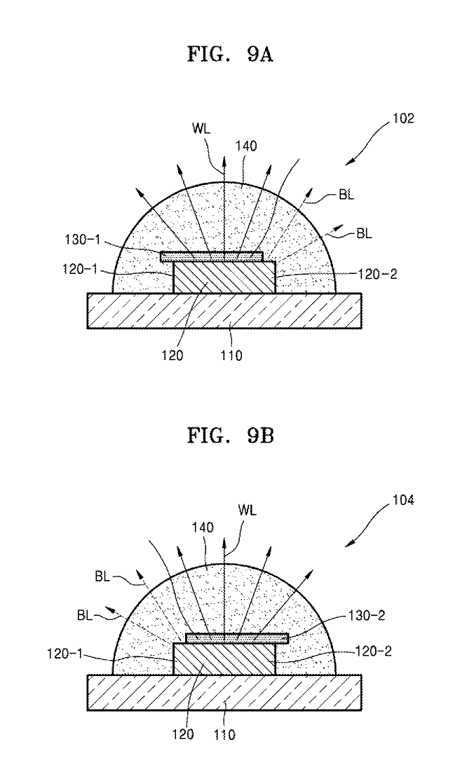

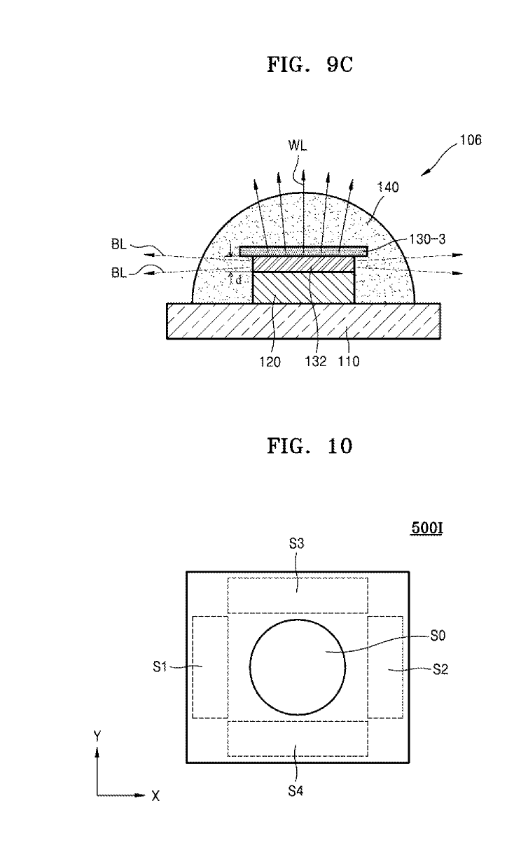

The controller 400 may include a microprocessor 410 and a memory 420. The microprocessor 410 may detect blue light from an optical image that is transferred from the photographing unit 300. The microprocessor 410 may determine the presence or absence of the defect of the light-emitting device package 100 by calculating a ratio of a region where the captured blue light is recorded with respect to an entire region of the optical image. The memory 420 may store information of the light-emitting device package 100 that is determined as defective by the microprocessor 410. The controller 400 will be described below in detail with reference to FIGS. 9 to 11.

The display unit 500 may display information including the ratio of the region where the blue light is recorded or the defect presence or absence, which is transferred from the controller 400.

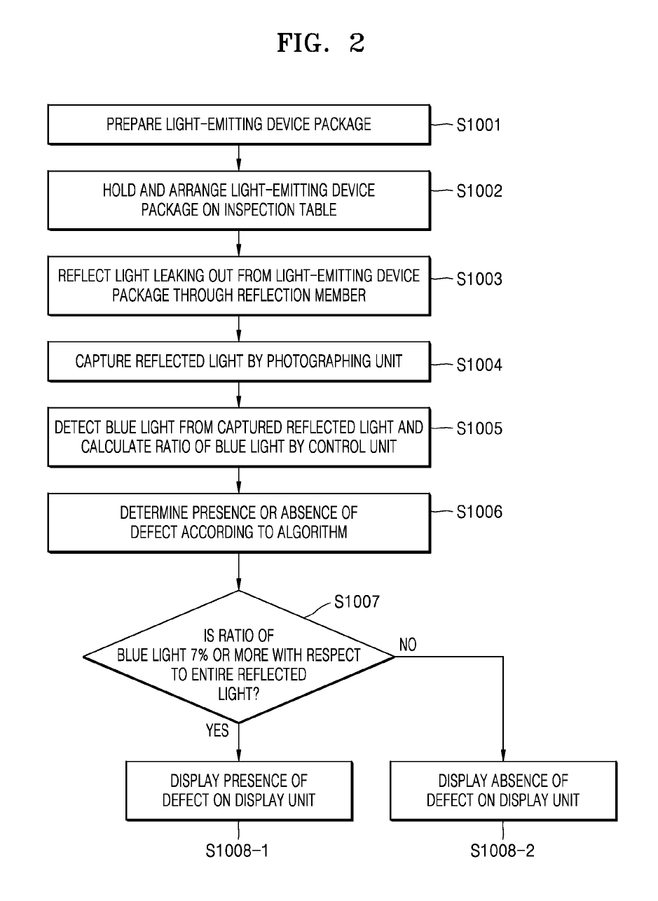

FIG. 2 is a flowchart of a method of manufacturing a light-emitting device package 100, according to an embodiment of the inventive concept.

Referring to FIG. 2, the method of manufacturing the light-emitting device package 100, according to an embodiment of the present invention, may include: preparing a light-emitting device package 100 (S1001); holding and arranging the light-emitting device package 100 on an inspection apparatus 200 (S1002); reflecting light leaking out from the light-emitting device package 100 by a reflection member 220 (S1003); capturing, by using a photographing unit 300, the reflected light to form an optical image (S1004); detecting, by using a controller 400, a region where blue light is recorded from the optical image and calculating a ratio of the region where the blue light is recorded with respect to the entire optical image (S1005); determining a presence or absence of a defect of the light-emitting device package 100 according to an algorithm of the controller 400 (S1006); determining whether the region where the blue light is recorded in the optical image of the entire reflected light satisfies a specific determination criteria (for example, whether the ratio of the region where the blue light is recorded is equal to or greater than a predetermined ratio, for example, 7%, is set as a defect presence/absence determination criteria) (S1007); and displaying the defect presence or absence of the light-emitting device package 100 on a display unit 500 (S1008-1 and S1008-2). When the ratio of the region where the blue light is recorded with respect to the optical image of the entire reflected light is 7% or more, the defect presence may be displayed on the display unit 500 (S1008-1). When the ratio of the region where the blue light is recorded with respect to the optical image of the entire reflected light is less than 7%, the defect absence may be displayed on the display unit 500 (S1008-2). The exemplary embodiment of the present invention illustrates the ratio of 7% for the specific determination criteria, but the present invention is not limited thereto.

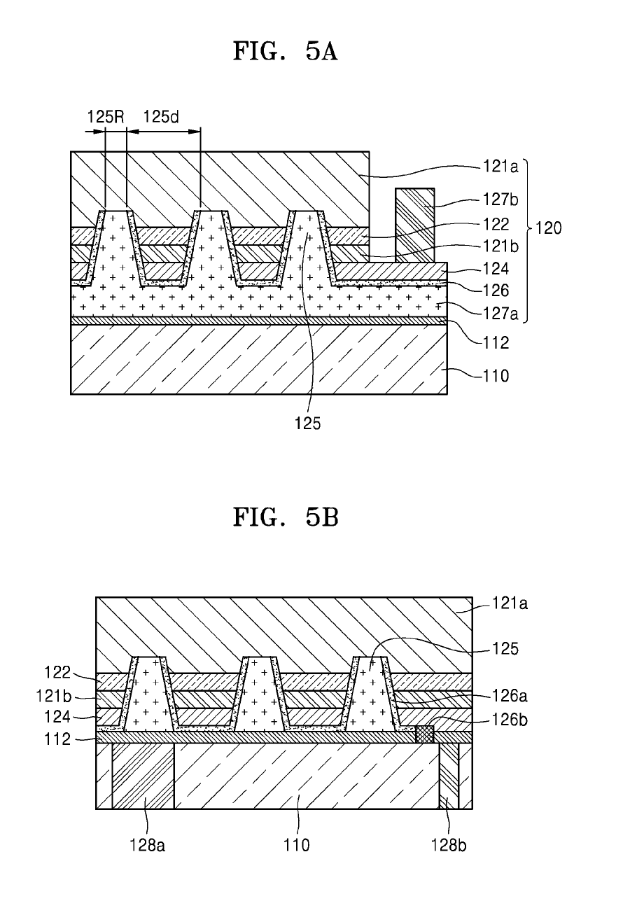

The operation S1001 of preparing the light-emitting device package 100 may include: forming a light-emitting device 120 (see FIGS. 4, 5A, and 5B) on a substrate 110 (see FIG. 4); forming a phosphor layer 130 (see FIG. 4) covering the light-emitting device 120; and forming a lens unit 140 (see FIG. 4) covering a top surface of the substrate 110, the light-emitting device 120, and the phosphor layer 130. The light-emitting device package 100 will be described below in detail with reference to FIG. 4.

The operation S1002 of holding and arranging the light-emitting device package 100 on the inspection apparatus 200 may include: holding the light-emitting device package 100 on the holder 210; and coupling one side of the light-emitting device package 100 by the coupling groove portions 230 and 232 (see FIG. 7) formed on the side of the holder 210.

The operation S1005 of detecting, by using the controller 400, the blue light from the entire reflected light may include: selectively detecting, by using the controller 400, blue light having a wavelength of about 400 nm to about 500 nm; and executing, by using the controller 400, an algorithm of calculating the ratio of the region where the blue light is recorded with respect to the optical image of the entire reflected light.

The operation S1006 of determining, by using the controller 400, the presence or absence of the defect of the light-emitting device package 100 may include: dividing the optical image transferred from the photographing unit 300 into predetermined regions; and executing an algorithm of calculating a ratio of an area of the region where the blue light is recorded with respect to an area of the divided region.

In the operation S1007 of determining whether the ratio of the blue light is 7% with respect to the image of the entire reflected light, the defect presence/absence criteria of the light-emitting device package 100 is that the ratio of the region where the blue light is recorded is 7% with respect to the entire image of the reflected light captured by the photographing unit 300, but the present disclosure is not limited to the predetermined ratio of 7%.

FIG. 3 is a conceptual diagram of a method of manufacturing a light-emitting device package 100, according to an embodiment of the present invention.

Referring to FIG. 3, the light-emitting device package 100 may be held on an inspection apparatus 200. In the light-emitting device package 100, white light WL, green light GL, or red light RL may be emitted by a light-emitting device 120 and a phosphor layer 130. Blue light BL may leak out from the light-emitting device 120 due to coating failure of the phosphor layer 130 or other causes. The light emitted by the light-emitting device package 100 may arrive at a photographing unit 300 and be captured by the photographing unit 300. The photographing unit 300 may image the light incident from the light-emitting device package 100. An optical image formed by the photographing unit 300 may be transferred to a controller 400. The controller 400 may detect the region where the blue light BL is recorded from the entire optical image transferred from the photographing unit 300 and calculate the ratio of the region where the blue light BL is recorded with respect to the entire optical image. The controller 400 may transfer, to the display unit 500, information including the ratio of the region where the blue light BL is recorded with respect to the entire optical image. The display unit 500 may display the ratio information.

The light-emitting device package 100 may include a substrate 110, a light-emitting device 120 formed on the substrate 110, a phosphor layer 130 covering the light-emitting device 120, and a lens unit 140 covering a top surface of the substrate 110, the light-emitting device 120, and the phosphor layer 130. The light-emitting device package 100 will be described below in detail with reference to FIG. 4.

The inspection apparatus 200 may include a holder 210, a fixing portion 212, a first reflection member 220, and a second reflection member 222. The holder 210 and the first reflection member 220 have the same material and structure as those described above. The fixing portion 212 has the same material and structure as those of the holder 210 and the first reflection member 220 and is detachable from the holder 210. After the operation of holding the light-emitting device package 100 on the holder 210, the fixing portion 212 may come into contact with one side of the holder 210 and be coupled and fixed to one side of the light-emitting device package 100. The operation of holding the light-emitting device package 100 on the holder 210 and the operation of coupling the light-emitting device package 100 by the fixing portion 212 will be described below in detail with reference to FIG. 7.

The white light WL and the blue light BL emitted by the light-emitting device package 100 may arrive at the photographing unit 300 and be optically imaged by the photographing unit 300. The light-emitting device package 100 may emit the white light WL, and the blue light BL may leak out due to failure in the process of manufacturing the light-emitting device package 100. Types of defects of the light-emitting device package 100 will be described in detail with reference to FIGS. 9A to 9C.

The photographing unit 300 may include a lens unit 310 and a camera unit 320. According to an exemplary embodiment of the inventive concept, the lens unit 310 may include an imaging lens, a light receiving portion, and a light collecting portion. The lens unit 310 may capture the white light WL and the blue light BL emitted by the light-emitting device package 100 through the light receiving portion and the light collecting portion. The light receiving portion and the light collecting portion may collect the captured light and transfer the collected light to an image sensor of the camera unit 320. The camera unit 320 may image the white light WL and the blue light BL captured by the lens unit 310 and record the imaged white light and the imaged blue light. According to an exemplary embodiment of the inventive concept, the camera unit 320 may be a charge coupled device (CCD) camera, a complementary metal-oxide semiconductor (CMOS) image sensor, or a lateral buried charge accumulator and sensing transistor array (LBCAST).

The controller 400 may include a microprocessor 410 and a memory 420. The microprocessor 410 may detect the region where the blue light BL is recorded from the optical image captured and recorded by the photographing unit 300. Specifically, the microprocessor 410 may selectively detect the blue light BL having a wavelength of about 400 nm to about 500 nm among wavelengths of the light recorded in the optical image. The microprocessor 410 may execute an algorithm of calculating the ratio of the region where the blue light BL is recorded with respect to the entire optical image captured by the photographing unit 300. According to an exemplary embodiment of the inventive concept, the microprocessor 410 may divide the optical image into regions preset by the algorithm and execute the algorithm of calculating the ratio of the area of the region where the blue light BL is recorded with respect to the area of the divided region. The microprocessor 410 may determine the presence or absence of the defect of the light-emitting device package 100 according to the calculated ratio. The memory 420 may store information of the presence or absence of the defect determined by the microprocessor 410. The memory 420 may store the algorithm that performs the operation of determining the presence or absence of the defect, which is performed by the microprocessor 410.

The display unit 500 may display information on the ratio of the region where the blue light BL is recorded with respect to the entire region of the optical image and information of the presence or absence of the defect of the light-emitting device package 100, which are transferred from the controller 400. The display unit 500 may be a display device including a monitor, a screen, or the like, which is widely used.

The light-emitting device packages determined as non-defective and the light-emitting device packages determined as defective may be classified and stored in different containers.

FIG. 4 is a cross-sectional view of a light-emitting device package 100 corresponding to the preparing operation in the method of manufacturing the light-emitting device package 100, according to an embodiment of the inventive concept.

The light-emitting device package 100 may include a substrate 110, a light-emitting device 120 formed on the substrate 110, a phosphor layer 130 covering the light-emitting device 120, and a lens unit 140 covering a top surface of the substrate 110, the light-emitting device 120, and the phosphor layer 130. According to an exemplary embodiment of the present invention, the light-emitting device package 100 may further include a wire 150 electrically connecting the light-emitting device 120 and the substrate 110.

The substrate 110 may be a ceramic substrate, a printed circuit board (PCB), or a metal core PCB (MCPCB) in which an insulating material, such as a resin, is coated on a surface of a metal plate. According to an exemplary embodiment of the present invention, the substrate 110 may be a ceramic substrate in which a via hole for electrode connection is formed.

The light-emitting device 120 may be mounted on the substrate 110. The light-emitting device 120 may be mounted on the substrate 110 by one selected from the group consisting of a wire bonding, a eutectic bonding, a die bonding, and a surface mounting technology (SMT). The light-emitting device 120 will be described below in detail with reference to FIGS. 5A and 5B.

The phosphor layer 130 may be formed to cover a top surface and/or a side surface of the light-emitting device 120. According to an exemplary embodiment of the present invention, the phosphor layer 130 may be made of one selected from the group consisting of an inorganic powder, an organic material, a resin layer containing a wavelength conversion material (P) such as a quantum dot, a glass layer, and a ceramic layer. The resin layer, the glass layer, or the ceramic layer may be made of a uniform film having a thickness of about 5 μm to about 500 μm or a coating layer having a non-uniform thickness. Therefore, the phosphor may be transparent or translucent. For example, when the phosphor is made of a silicon resin layer containing a yellow phosphor, the phosphor may be provided with a translucent yellowish layer.

The phosphor may be excited from blue light emitted from the light-emitting device 120 and be converted to light of a different wavelength. The phosphor may include two or more types of materials so as to convert the light emitted from the light-emitting device 120 to light of different wavelengths. The light obtained after conversion from the phosphor and the non-converted light may be mixed with each other to output white light.

According to an exemplary embodiment of the present invention, the light emitted by the light-emitting device 120 may be blue light, and the phosphor may be made of at least one phosphor selected from the group consisting of a green phosphor, a yellow phosphor, a golden yellow phosphor, and a red phosphor.

The lens unit 140 may be formed to cover the top surface of the substrate 110, the light-emitting device 120, and the phosphor. The lens unit 140 may serve to reflect, collect, and distribute light emitted by the light-emitting device 120 and may be made of a transparent resin in which a refractive index of the emitted light is greater than 1. For example, the lens unit 140 may be made of at least one selected from the group consisting of a glass, a silicon resin, an epoxy resin, an acryl resin, polycarbonate, and poly methyl meth acrylate (PMMA). The lens unit 140 may be formed using various molding methods, depending on a manufacturing method. Examples of the molding methods may include a compress molding, a transfer molding, an injection molding, and a hybrid molding. The lens unit 140 may have various shapes. However, according to an exemplary embodiment of the present invention, the lens unit 140 is formed to have a convex dome shape.

FIGS. 5A and 5B are cross-sectional views illustrating the structure of the light-emitting device 120 in the preparing operation in the method of manufacturing the light-emitting device package 100, according to an embodiment of the inventive concept.

Referring to FIGS. 5A and 5B, the light-emitting device 120 may be mounted on the substrate 110 by one selected from the group consisting of a wire bonding, a eutectic bonding, a die bonding, and an SMT. According to an exemplary embodiment of the present invention, the light-emitting device 120 may include a bonding layer 112 that is made of AuSn by a die bonding using a eutectic bonding. The bonding layer 112 may be formed on the substrate 110. The light-emitting device 120 may be a nitride-based semiconductor light-emitting diode (LED) chip. The light-emitting device 120 may include a light-emitting stack structure including a first conductivity-type semiconductor layer 121a, a second conductivity-type semiconductor layer 121b, and an active layer 122 disposed between the first conductivity-type semiconductor layer 121a and the second conductivity-type semiconductor layer 121b.

According to an exemplary embodiment of the present invention, the light-emitting device 120 may include one or more contact holes that are electrically insulated from the second conductivity-type semiconductor layer 121b and the active layer 122 and extend to at least a portion of the first conductivity-type semiconductor layer 121a, so as to be electrically connected to the first conductivity-type semiconductor layer 121a. The light-emitting device 120 may include an electrode layer including a conductive via 125 that is formed by filling the inside of the contact hole with a conductive material.

In order to reduce a contact resistance, the number, a shape, and a pitch of the contact holes, and a contact area between the contact hole and the first and second conductivity-type semiconductor layers 121a and 121b may be appropriately adjusted. A current flow may be improved by arranging the contact holes along rows and columns in various forms. In this case, the conductive via 125 may be electrically isolated from the active layer 112 and the second conductivity-type semiconductor layer 121b that are surrounded by a via insulation film 126.

In a region where the plurality of conductive vias 125 formed in the rows and the columns contact the first conductivity-type semiconductor layer 121a, the number of the conductive vias 125 and the contact area may be adjusted such that the contact area is in the range of about 1% to about 5% with respect to the planar area of the light-emitting stack structure. In the region contacting the first conductivity-type semiconductor layer 121a, a diameter 125R of the conductive via 125 may be in the range of about 5 μm to about 50 μm, and the number of the conductive vias 125 may be 1 to 50 per the region of the light-emitting stack structure according to the area of the region of the light-emitting stack structure. The number of the conductive vias 125 is different according to the area of the region of the light-emitting stack structure. However, the number of the conductive vias 125 may be two or more, and the conductive vias 125 may be arranged in a matrix form in which a distance 125d between the conductive vias 125 is in the range of about 100 μm to about 500 μm. Specifically, the distance 125d between the conductive vias 125 may be in the range of about 150 μm to about 450 μm. If the distance 125d between the conductive vias 125 is less than 10 μm, the number of the vias is increased and the light-emitting area is relatively decreased, resulting in a reduction in light emission efficiency. If the distance 125d between the conductive vias 125 is greater than 500 μm, a current diffusion becomes difficult and light emission efficiency is degraded. A depth of the conductive via 125 may be different according to a thickness of the second conductivity-type semiconductor layer 121b and a thickness of the active layer 122. For example, the depth of the conductive via 125 may be in the range of about 0.5 μm to about 5.0 μm.

The first conductivity-type semiconductor layer 121a may be a nitride semiconductor layer satisfying n-type AlₓIn_{y}Ga_{1-x-y}N (0≦x<1, 0≦y<1, 0≦x+y<1), and an n-type impurity may be silicon (Si). For example, the first conductivity-type semiconductor layer 121a may be n-type GaN. The active layer 122 may have a multi quantum well (MQW) structure in which a quantum well layer and a quantum barrier layer are alternately stacked. For example, in the case of a nitride semiconductor, the active layer 122 may have a GaN/InGaN structure. On the other hand, the active layer 122 may have a single quantum well (SQM) structure. The second conductivity-type semiconductor layer 121b may be a nitride semiconductor layer satisfying p-type AlₓIn_{y}Ga_{1-x-y}N (0≦x<1, 0≦y<1, 0≦x+y<1), and a p-type impurity may be magnesium (Mg). For example, the second conductivity-type semiconductor layer 121b may be p-type AlGaN/GaN.

Referring to FIG. 5A, a first electrode 127a may be connected to the first conductivity-type semiconductor layer 121a through the conductive via 125. An ohmic contact layer 124 may be formed on a bottom surface of the second conductivity-type semiconductor layer 121b, and a second electrode 127b may be formed on a top surface of the ohmic contact layer 124. For example, the second electrode 127b above the second conductivity-type semiconductor layer 121b may include at least one material selected from the group consisting of indium tin oxide (ITO), zinc oxide (ZnO), a graphene layer, silver (Ag), nickel (Ni), aluminium (Al), rhodium (Rh), palladium (Pd), iridium (Ir), rubidium (Ru), magnesium (Mg), zinc (Zn), platinum (Pt), and gold (Au) and may have a structure of two or more layers, such as Ni/Ag, Zn/Ag, Ni/Al, Zn/Al, Pd/Ag, Pd/Al, Ir/Ag, Ir/Au, Pt/Ag, Pt/Al, and Ni/Ag/Pt. The first electrode 127a and the second electrode 127b are not limited thereto. The first electrode 127a and the second electrode 127b may include a material, such as Ag, Ni, Al, Rh, Pd, Ir, Ru, Mg, Zn, Pt, Au and may have a single layer or a structure of two or more layers. If necessary, the first electrode 127a and the second electrode 127b may be implemented in a flip chip structure by using a reflective electrode structure. For example, the first electrode 127a may have a structure with an Al/Ti/Pt/Ti layer (for example, an Al/Ti/Pt/Ti/Cr/Au/Sn solder, an Al/Ti/Pt/Ti/Pt/Ti/Pt/Ti/Ni/Pt/Au/Sn solder, or an Al/Ti/Pt/Ti/Pt/Ti/Pt/Ti/Au/Ti/AuSn) or a structure with a Cr/Au layer (for example, Cr/Au/Pt/Ti/Ti/TiN/Ti/Ni/Au). The second electrode 127b may have a structure with an Ag layer (for example, Ag/Ti/Pt/Ti/TiN/Ti/TiN/Cr/Au/Ti/Au).

Referring to FIG. 5B, the first electrode 128a and the second electrode 128b may be formed to vertically pass through the substrate 110. The first electrode 128a may be connected to the bonding layer 112 formed on the top surface of the first electrode 128a and thus electrically connected to the first conductivity-type semiconductor layer 121a through the conductive via 125. The second electrode 128b may be connected to the ohmic contact layer 124 and thus electrically connected to the second conductivity-type semiconductor layer 121b. The conductive via 125 may be electrically isolated from the active layer 122 and the second conductivity-type semiconductor layer 121b that are surrounded by a via insulation film 126a. The bonding layer 112 may be isolated by an electrode insulation film 126b, and the first electrode 128a and the second electrode 128b may be electrically isolated from each other.

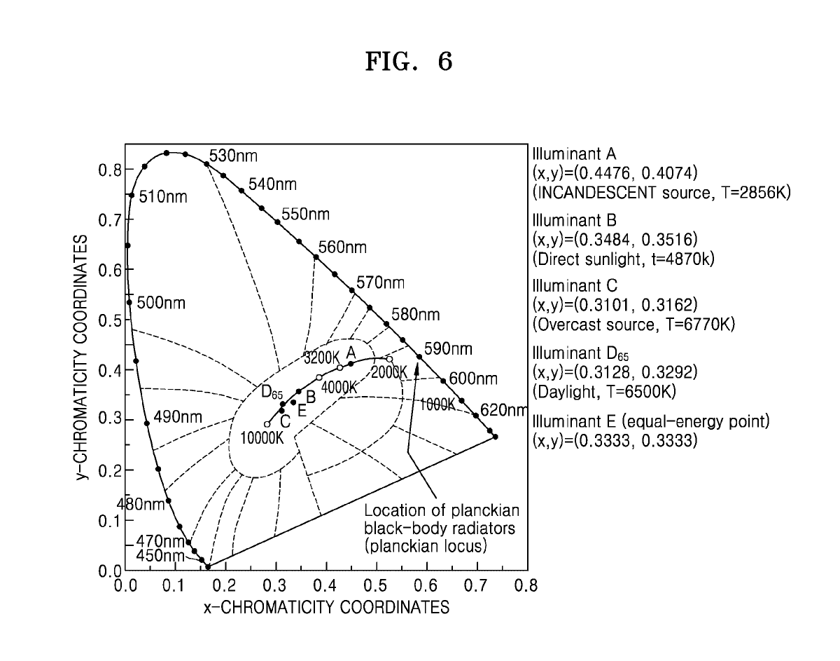

An energy gap occurs when a hole of the p-type semiconductor and an electron of the n-type semiconductor are combined with each other, and light energy corresponding to the energy gap is generated. The light-emitting device 120 may emit light through such a principle. The light-emitting device 120 may be a blue LED that emits blue light. White light having two or more peak wavelengths may be generated while the blue light emitted by the light-emitting device 120 passes through the red, yellow, and green phosphors. (x, y) coordinates of the white light in the CIE 1931 coordinate system may be positioned on a line segment connecting coordinates (0.4476, 0.4074), (0.3484, 0.3516), (0.3101, 0.3162), (0.3128, 0.3292), and (0.3333, 0.3333) or may be positioned in a region surrounded by the line segment and a black-body radiator spectrum. A color temperature of the white light may have a value corresponding to about 2,000K to about 20,000K (see FIG. 6).

FIG. 6 illustrates the CIE 1931 coordinate system for describing various examples of the wavelength conversion material adoptable to the phosphor layer 130 of the light-emitting device package 100, according to an embodiment of the present invention.

The light-emitting device 120 (see FIGS. 4, 5A, and 5B), according to an exemplary embodiment of the present invention, may be an LED that emits blue light. Also, the phosphor layer 130 (see FIG. 4) may convert the blue light emitted by the light-emitting device 120 to at least one selected from the group consisting of a yellow color, a green color, a red color, and an orange color, and mix the blue light with the unconverted blue light to emit white light.

On the other hand, when the light-emitting device 120 (see FIGS. 4, 5A, and 5B) emits ultraviolet light, the phosphor may include phosphors that emit blue light, green light, and red light. In this case, the light-emitting device package 100 including the phosphor may adjust a color rendering index (CRI) from a level of sodium (Na) light (CRI: 40) to a level of solar light (CRI: 100). The light-emitting device package 100 may generate a variety of white light having a color temperature of about 2000K to about 20,000K. If necessary, the light-emitting device package 100 may adjust an illumination color according to a surrounding atmosphere or a mood by generating infrared light or visible light, such as a violet color, a blue color, a red color, and an orange color. In addition, the light-emitting device package 100 may generate light of a specific wavelength so as to promote the growth of plants.

In the CIE 1931 coordinate system illustrated in FIG. 6, (x, y) coordinates of light generated by a package module constituted by one or more package selected from the group consisting of a white light-emitting package including at least one selected from a yellow phosphor, a green phosphor, and a red phosphor in the light-emitting device 120 emitting blue light (see FIGS. 4, 5A, and 5B), a green or red light-emitting package including at least one selected from a green phosphor and a red phosphor in the light-emitting device 120 emitting blue light, a green light-emitting device package including no phosphor, and a red light-emitting device package including no phosphor may be positioned on the line segment connecting (0.4476, 0.4074), (0.3484, 0.3516), (0.3101, 0.3162), (0.3128, 0.3292), (0.3333, 0.3333). Alternatively, the (x, y) coordinates may be positioned in a region surrounded by the line segment and a black-body radiator spectrum. A color temperature of the white light may be in the range of about 2000K to about 20,000K.

A phosphor, which is an example of a wavelength conversion member, will be described below in detail with reference to FIG. 6.

The phosphor may have the following empirical formulas and colors.

Oxide: yellow color and green color Y₃Al₅O₁₂:Ce, Tb₃Al₅O₁₂:Ce, Lu₃Al₅O₁₂:Ce

Silicate: yellow color and green color (Ba,Sr)₂SiO₄:Eu, yellow color and orange color (Ba,Sr)₃SiO₅:Ce

Nitride: green color p-SiAlON:Eu, yellow color L₃Si₆O₁₁:Ce, orange color α-SiAlON:Eu, red color CaAlSiN₃:Eu, Sr₂Si₅N₈:Eu, SrSiAl₄N₇:Eu, SrLiAl₃N₄:Eu,

Ln₄₋ₓ(EuzM_{1-z})ₓSi_{12-y}Al_{y}O_{3+x+y}N_{18-x-y}(0.5≦x≦3,0<z<0.3,0<y≦4) (1)

In Formula (1), Ln may be at least one element selected from the group consisting of group IIIa elements and rare-earth elements, and M may be at least one element selected from the group consisting of calcium (Ca), barium (Ba), strontium (Sr), and magnesium (Mg).

Fluoride: KSF-based red color K₂SiF₆:Mn₄+, K2TiF6:Mn4+, NaYF4:Mn4+, NaGdF4:Mn4+

The composition of the phosphor needs to basically conform to stoichiometry, and the respective elements may be partially or entirely substituted by other elements included in the respective groups of the periodic table. For example, strontium (Sr) may be partially or entirely substituted by at least one selected from the group consisting of barium (B a), calcium (Ca), and magnesium (Mg) of alkaline-earth group II, and Y may be partially or entirely substituted by at least one selected from the group terbium (Tb), lutetium (Lu), scandium (Sc), and gadolinium (Gd). In addition, europium (Eu), which is an activator, may be partially or entirely substituted by at least one selected from the group consisting of cerium (Ce), terbium (Tb), praseodymium (Pr), erbium (Er), and ytterbium (Yb) according to a desired energy level. The activator may be applied solely or a sub activator may be additionally applied to change characteristics.

Furthermore, as phosphor alternatives, materials such as quantum dot (QD) may be applied. A phosphor and a QD may be used in an LED solely or in combination.

The quantum dot may have a structure including a core (3 nm to 10 nm) such as CdSe or InP, a shell (0.5 nm to 2 nm) and a core such as ZnS or ZnSe, or a ligand for stabilizing a shell and may implement various colors according to sizes.

Table 1 below shows types of phosphors according to applications of a white light-emitting device using a blue LED (440 nm to 460 nm).

TABLE 1

| Usage | Phosphor |
|---|---|
| LED TV BLU | β-SiAlON: Eu2+ |
| | (Ca, Sr)AlSiN3: Eu2+ |
| | L3Si6O11: Ce3+ |
| | K2SiF6: Mn4+ |
| | K2TiF6: Mn4+ |
| | NaYF4: Mn4+ |
| | NaGdF4: Mn4+ |
| | SrLiAl3N4: Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4) (1) |
| Illumination | Lu3Al5O12: Ce3+ |
| | Ca-α-SiAlON: Eu2+ |
| | L3Si6N11: Ce3+ |
| | (Ca, Sr)AlSiN3: Eu2+ |
| | Y3Al5O12: Ce3+ |
| | K2SiF6: Mn4+ |
| | K2TiF6: Mn4+ |
| | NaYF4: Mn4+ |
| | NaGdF4: Mn4+ |
| | SrLiAl3N4: Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4) (1) |
| Side View | Lu3Al5O12: Ce3+ |
| (Mobile, Note PC) | Ca-α-SiAlON: Eu2+ |
| | L3Si6N11: Ce3+ |
| | (Ca, Sr)AlSiN3: Eu2+ |
| | Y3Al5O12: Ce3+ |
| | (Sr, Ba, Ca, Mg)2SiO4: Eu2+ |
| | K2SiF6: Mn4+ |
| | K2TiF6: Mn4+ |
| | NaYF4: Mn4+ |
| | NaGdF4: Mn4+ |
| | SrLiAl3N4: Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4) (1) |
| Electrical | Lu3Al5O12: Ce3+ |
| Component | Ca-α-SiAlON: Eu2+ |
| (Head Lamp, etc.) | L3Si6N11: Ce3+ |
| | (Ca, Sr)AlSiN3: Eu2+ |
| | Y3Al5O12: Ce3+ |
| | K2SiF6: Mn4+ |
| | K2TiF6: Mn4+ |
| | NaYF4: Mn4+ |
| | NaGdF4: Mn4+ |
| | SrLiAl3N4: Eu |
| | Ln₄₋ₓ(Eu_{z}M_{1-z})ₓSi_{12-y}Al_{y}O_{3+x+y}N_{18-x-y} |
| | (0.5 ≦ x ≦ 3, 0 < z < 0.3, 0 < y ≦ 4) (1) |

In Formula (1) of Table 1, Ln may be at least one element selected from the group consisting of group IIIa elements and rare-earth elements, and M may be at least one element selected from the group consisting of calcium (Ca), barium (Ba), strontium (Sr), and magnesium (Mg).

Phosphors or quantum dots may be applied by using at least one selected from the group consisting of a method of spraying phosphors or quantum dots on a light-emitting device, a method of covering as a film, and a method of attaching as a sheet of film or ceramic phosphor.

As the spraying method, dispensing or spray coating is commonly used. The dispensing includes a pneumatic method and a mechanical method such as screw or linear type. Through a jetting method using a piezoelectric field effect, an amount of dotting may be controlled through a very small amount of discharging and color coordinates may be controlled therethrough. In case of a method of collectively applying phosphors on a wafer level or on a light-emitting device by using a spray method, productivity may be enhanced and a thickness may be easily controlled.

The method of covering phosphors or quantum dots as a film on a light-emitting device may include electrophoresis, screen printing, or a phosphor molding method, and these methods may have a difference according to whether a lateral surface of a chip is required to be coated.

When two or more types of phosphor layers having different light-emitting wavelengths are stacked, a distributed Bragg reflector (DBR) layer may be included between the respective layers in order to minimize wavelength re-absorption and interference between the chips and the phosphor layers. In order to form a uniform coated film, after a phosphor is fabricated as a film or a ceramic form and attached to a chip.

In order to differentiate light efficiency and light distribution characteristics, a phosphor layer serving as a light conversion material may be positioned in a remote form, and in this case, the light conversion material may be positioned together with a material such as a light-transmissive polymer, glass, or the like, according to durability and heat resistance.

A phosphor applying technique plays the most important role in determining light characteristics in a light-emitting device, so techniques of controlling a thickness of a phosphor application layer, a uniform phosphor distribution, and the like, have been variously researched.

A quantum dot may also be positioned in a light-emitting device in the same manner as that of a phosphor, and may be positioned in glass or light-transmissive polymer material to perform optical conversion.

FIG. 7 is a perspective view illustrating an inspection apparatus 200 and a light-emitting device package 100 corresponding to the inspecting operation in the method of manufacturing the light-emitting device package 100, according to an embodiment of the present invention.

Referring to FIG. 7, the inspection apparatus 200 may include a holder 210, a fixing portion 212, a first reflection member 220, and a second reflection member 222. The first reflection member 220 may be integrally formed with the holder 210. The second reflection member 222 may be integrally formed with the fixing portion 212.

A basic material of the holder 210 may be thoron or Vespel, and the surface of the holder 210 may be processed by a blackening method. The blackening method may perform surface processing by forming a black oxide film of ferrosoferric oxide (Fe₃O₄) on the surface of the inspection apparatus 200. Specifically, the blackening method may deposit only iron components by heating a processing liquid, in which an oxidizer and a reaction accelerator are added to an aqueous solution of 35% to 45% of sodium hydroxide (NaOH), to about 130° C. to about 150°. By processing the surface of the holder 210 using the above-described blackening method, it is possible to prevent light generated by the light-emitting device package 100 from being diffused and reflected from the surface of the holder 210.

The first reflection member 220 may be made of a different material from the holder 210 and be connected to the holder 210. The first reflection member 220 may be formed adjacent to three sides of four sides of the light-emitting device package 100 to surround the periphery of the light-emitting device package 100. The first reflection member 220 may be formed to be inclined at a predetermined angle with respect to the top surface of the holder 210. The first reflection member 220 may be formed to be inclined toward the light-emitting device package 100. According to an exemplary embodiment of the present invention, the first reflection member 220 may be formed to be inclined at an angle of about 30° to about 60° with respect to the top surface of the holder 210.

A coupling groove portion 230 may be formed such that a bottom surface of the first reflection member 220 and a side of the light-emitting device package 100 are fixed. The coupling groove portion 230 may fix the light-emitting device package 100 by tightly coupling the light-emitting device package 100 to the first reflection member 220.

The fixing portion 212 may be detachable from the holder 210 and the first reflection member 220. The fixing portion 212 may be made of the same material as that of the holder 210 and may have the same surface material as that of the holder 210. That is, the fixing portion 212 may be made of thoron or Vespel and the surface of the fixing portion 212 may be blackened. The fixing portion 212 may be moved in a first direction (X direction) to contact an exposed portion of the holder 210. The fixing portion 212 may include a coupling groove portion 232 formed on a bottom surface of the second reflection member 222. When the fixing portion 212 is moved to the first direction (X direction) to contact one side of the light-emitting device package 100, the coupling groove portion 232 may be coupled by the fixing portion 212 and the light-emitting device package 100.

The second reflection member 222 may be made of a different material from that of the fixing portion 212. As in the first reflection member 220, the second reflection member 222 may be formed to be inclined toward the light-emitting device package 100. As in the first reflection member 220, the second reflection member 222 may be formed to be inclined at a predetermined angle of, for example, about 30° to about 60°, with respect to the top surface of the holder 210.

The first reflection member 220 and the second reflection member 222 may be made of a material capable of reflecting blue light BL1 to BL3 leaking out from the light-emitting device package 100 and have the above-described structure. The first reflection member 220 and the second reflection member 222 may be made of a material capable of reflecting the blue light BL1 to BL3 on the inclined surface of the inspection apparatus 200. For example, the first reflection member 220 and the second reflection member 222 may be made of a material including chromium (Cr), carbon (C), molybdenum (Mo), manganese (Mn), nickel (Ni), vanadium (V), silicon (Si), copper (Cu), sulfur (S), or phosphorus (P). The blue light BL1 to BL3 leaking out from the light-emitting device package 100 may be reflected from the first reflection member 220 and the second reflection member 222 and arrive at the photographing unit 300 (see FIG. 3).

FIG. 8A is a plan view illustrating the inspection apparatus 200 and the light-emitting device package 100 corresponding to the inspecting operation in the method of manufacturing the light-emitting device package 100, according to an embodiment of the inventive concept, and FIG. 8B is a cross-sectional view taken along line VIII-VIII′ of FIG. 8A illustrating the inspection apparatus 200 and the light-emitting device package 100.

Referring to FIGS. 8A and 8B, the holder 210 and the fixing portion 212 may be connected in contact with each other. The light-emitting device package 100 may be held in the central portion of the inspection apparatus 200, and the four sides of the light-emitting device package 100 may be surrounded by the first reflection member 220 and the second reflection member 222. A current may flow through the light-emitting device package 100 through the electrode 240 passing through the bottom via of the holder 210. According to an exemplary embodiment of the present invention, the light-emitting device package 100 may supply a current to the light-emitting device from the bottom surface of the substrate through the first electrode 128a and the second electrode 128b formed in the via holes of the substrate.

FIGS. 9A to 9C are cross-sectional views for describing the cause of defects of light-emitting device packages 102, 104, and 106 in the process of manufacturing the light-emitting device packages, according to an embodiment of the present invention.

Referring to FIG. 9A, the light-emitting device package 102 may include a substrate 110, a light-emitting device 120 mounted on the substrate 110, a phosphor layer 130-1 covering a top surface and a first side 120-1 of the light-emitting device 120, and a lens unit 140 covering a top surface of the substrate 110, the light-emitting device 120, and the phosphor layer 130-1. As opposed to the phosphor layer 130 illustrated in FIG. 4, the phosphor layer 130-1 may be formed not to cover both sides of the light-emitting device 120. That is, the phosphor layer 130-1 may be formed to cover the first side 120-1 of the light-emitting device 120, without covering a second side 120-2 of the light-emitting device 120. As described above with reference to FIGS. 4 to 6, since the phosphor layer 130-1 includes a material capable of converting blue light BL emitted from the light-emitting device 120 to white light WL, blue light BL may be generated if the phosphor layer 130-1 does not cover the entire light-emitting device 120. The light-emitting device package 100, from which the blue light BL leaks out, may be determined as defective by the controller 400 (see FIG. 1).

As opposed to the light-emitting device package 104 illustrated in FIG. 9A, the light-emitting device package 104 illustrated in FIG. 9B is formed such that a phosphor layer 130-2 covers a second side 120-2 of a light-emitting device 120 and does not cover a first side 120-1 of the light-emitting device 120. Blue light emitted from the top surface and the first side 120-1 of the light-emitting device 120 is emitted as white light WL through the phosphor layer 130-2. However, blue light BL emitted from the second side 120-1 of the light-emitting device 120 is directly transmitted without passing through the phosphor layer 130-2, and thus, blue light BL may leak out. The light-emitting device package 104 may be determined as defective.

The light-emitting device package 106 illustrated in FIG. 9C may be formed such that a phosphor layer 130-3 is spaced apart from a light-emitting device 120 by a predetermined distance d. The predetermined distance d may occur in a process of forming the phosphor layer 130-3, that is, a process of forming an adhesive silicon layer 132 on the top surface of the light-emitting device 120, among in the processes of manufacturing the light-emitting device package 106. Since the phosphor layer 130-3 does not cover the top surface and the side of the light-emitting device 120 and is spaced apart by the predetermined distance d, only a part of the blue light BL emitted by the light-emitting device 120 is emitted as white light WL and the remaining blue light BL leaks out. Therefore, the light-emitting device package 106 may be determined as defective.

FIG. 10 is a diagram illustrating an optical image 500I displayed on a display unit 500 so as to describe a defect determining operation in a method of manufacturing the light-emitting device package 100, according to an embodiment of the inventive concept.

Referring to FIG. 10, the optical image 500I of the light-emitting device package 100, which is captured by the photographing unit 300 (see FIGS. 1 and 3) and is displayed on the display unit 500 (see FIGS. 1 and 3) under the control of the controller 400 (see FIGS. 1 and 3), may be divided into a light-emitting region S0, in which white light is generated in the lens unit 140 (see FIG. 4), and a region except for the light-emitting region S0 in the entire optical image 500I. The region except for the light-emitting region S0 in the entire optical image 500I may be divided into four regions around the light-emitting region S0. The four regions may include a first region S1 formed relatively on a left side in a first direction (X direction) with respect to the light-emitting region S0, a second region S2 formed relatively on a right side in the first direction (X direction) with respect to the light-emitting region S0, a third region S3 formed relatively on the upper side in a second direction (Y direction) with respect to the light-emitting region S0, and a fourth region S4 formed relatively on a lower side in the second direction (Y direction) with respect to the light-emitting region S0. In an exemplary embodiment of the inventive concept, the optical image 500I may be divided into four regions, except for the light-emitting region S0, but the inventive concept is not limited thereto.

Blue light may be detected in the four regions S1 to S4 except for the light-emitting region S0 of the entire optical image 500I. White light is emitted in the light-emitting region S0, but the defect of the light-emitting device package 100 may cause a leakage of blue light in the four regions S1 to S4 as exemplified in FIGS. 9A to 9C. The blue light may be detected by the controller 400 (see FIGS. 1 and 3), and the detected optical image 500I of the light-emitting device package 100 may be transferred to the display unit 500 (see FIGS. 1 and 3).

The presence or absence of the defect of the light-emitting device package 100 may be determined by the ratio of the blue light detected in the four regions S1 to S4 of the entire optical image 500I, except for the light-emitting region S0. That is, the presence or absence of the defect of the light-emitting device package 100 may be determined by calculating the ratio of the area of the region where the blue light is recorded with respect to the area of the four regions S1 to S4. According to an exemplary embodiment of the present invention, when the ratio of the area of the region where the blue light is recorded with respect to the area of the four regions S1 to S4 is equal to or greater than 7%, the relevant light-emitting device package 100 may be determined as defective. However, the ratio of 7% is merely an example of the defect determination, and the inventive concept is not limited thereto. The ratio of the area of the region where the blue light is recorded with respect to the area of the four regions S1 to S4 may be calculated by the controller 400 (see FIGS. 1 and 3).

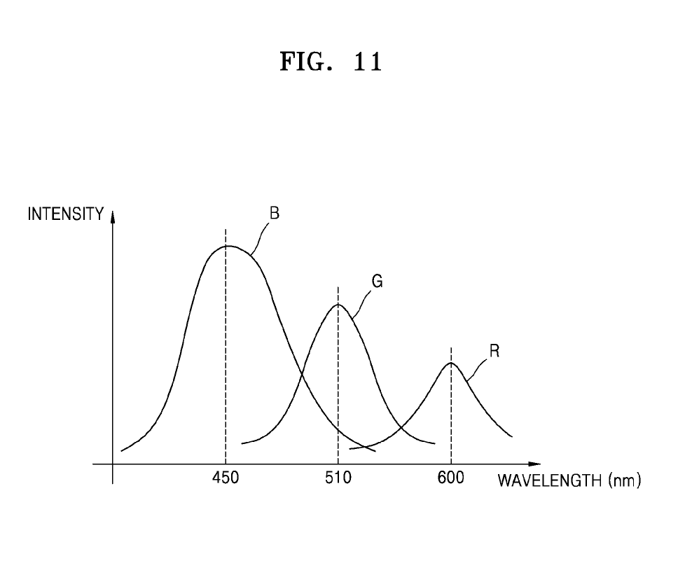

FIG. 11 illustrates a coordinate system of the light-emitting wavelength of the light-emitting device 120 (see FIGS. 4, 5A, and 5B) so as to describe the defect determining operation of the controller 400 in the method of manufacturing the light-emitting device package 100, according to an embodiment of the inventive concept.

The blue light generated by the light-emitting device 120 (see FIG. 4) of the light-emitting device package 100 (see FIG. 4) may be emitted as white light through the phosphor layer 130 (see FIG. 4). The intensity of the light emitted by the light-emitting device package 100 may have various wavelength values. The light emitted by the light-emitting device package 100 may be emitted as a blue color B, a green color G, or a red color R according to wavelengths having the maximum intensity. The wavelengths having the maximum intensity are different according to the types of the light-emitting device and the phosphor. Specifically, the blue color B may have the maximum intensity at a wavelength of about 450 nm (about 430 nm to about 470 nm), the green color G may have the maximum intensity at a wavelength of about 510 nm (about 500 nm to about 550 nm), and the red color R may have the maximum intensity at a wavelength of about 600 nm (about 590 nm to about 650 nm).

The controller 400 (see FIGS. 1 to 3) may detect blue light having a wavelength of about 450 nm which corresponds to the blue color B. According to an exemplary embodiment of the present invention, the controller 400 may detect blue light having a wavelength of about 400 nm to about 500 nm.

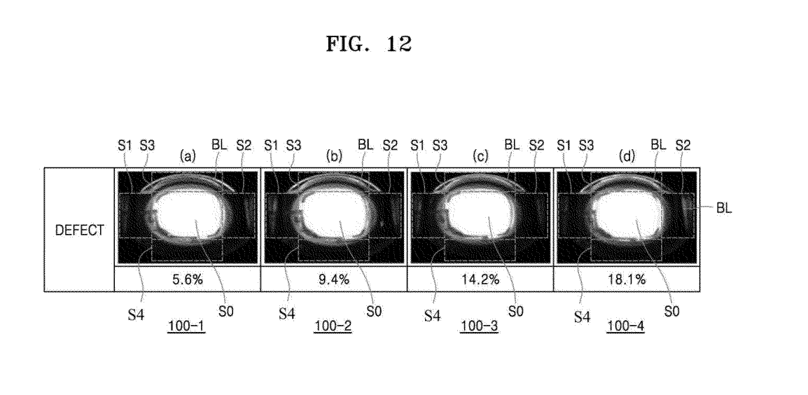

FIG. 12 illustrates an exemplary image for describing the defect determining operation of the controller in the method of manufacturing the light-emitting device package 100, according to an embodiment of the present invention.

A light-emitting device package 100-1 illustrated in FIG. 12 may be determined as non-defective because the ratio of the area of the region where blue light is recorded with respect to the area of the regions S1 to S4 in the entire optical image, except for the light-emitting region S0, is 5.6%. A light-emitting device package 100-2 illustrated in FIG. 12 may be determined as defective because the ratio of the area of the region where blue light is recorded with respect to the area of the regions S1 to S4 in the entire optical image, except for the light-emitting region S0, is 9.4%. A light-emitting device package 100-3 illustrated in FIG. 12 may be determined as defective because the ratio of the area of the region where blue light is recorded with respect to the area of the regions S1 to S4 in the entire optical image, except for the light-emitting region S0, is 14.2%. Similarly, a light-emitting device package 100-4 illustrated in FIG. 12 may be determined as defective because the ratio of the area of the region where blue light is recorded with respect to the area of the regions S1 to S4 in the entire optical image, except for the light-emitting region S0, is 18.1%.

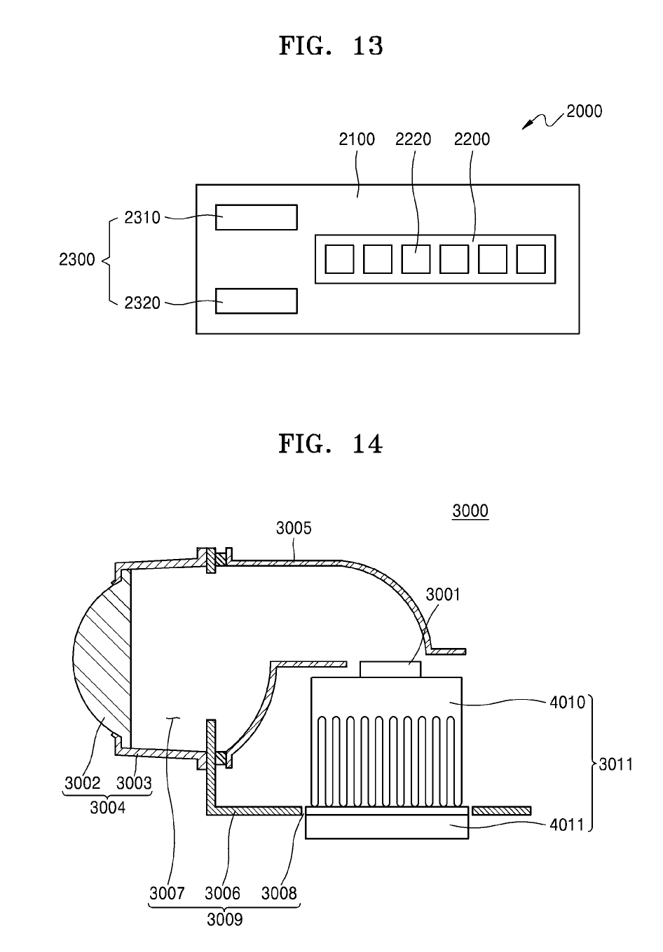

FIG. 13 is a conceptual diagram of an illumination system 2000, to which a light-emitting device package 100 by a method of manufacturing a light-emitting device package is applied, according to an embodiment of the inventive concept.

Referring to FIG. 13, the illumination system 2000 may include a light-emitting device module 2200 disposed on a structure 2100, and a power supply 2300. The light-emitting device module 2200 may include a plurality of light-emitting devices 2200 or a light-emitting device package 2220. The light-emitting device module 2200 may include the light-emitting device package 100 described above with reference to FIGS. 1, 3, 4, and 7. The plurality of light-emitting devices 2220 may be the light-emitting devices 120 or the light-emitting device package 100 described above with reference to FIGS. 1, 3, 4, and 7.

The power supply 2300 may include an interface 2310 that receives power, and a power controller 2320 that controls power supplied to the light-emitting device module 2200. The interface 2310 may include a fuse that blocks an overcurrent, and an electromagnetic wave shield filter that shields an electromagnetic interference signal. The power controller 2320 may include a rectification/smoothing unit that converts an AC voltage to a DC voltage when the AC power is input as the power, and a constant voltage controller that changes the DC voltage to a voltage suitable for the light-emitting device module 2200. The power supply 2300 may include a feedback circuit that performs a preset amount of light with an amount of light emitted by each of the light-emitting devices 2220, and a memory device that stores information such as desired luminance, color rendering index, and the like.

The illumination system 2000 may be used as an indoor lighting or an outdoor lighting. Examples of the indoor lighting may include a backlight unit for a display device, such as a liquid crystal display with an image panel, a lamp, and a flat panel lighting, and examples of the outdoor lighting may include a signboard and a signpost. In addition, the illumination system 2000 may be used in various transportations, such as a vehicle, a vessel, and an airplane, household appliances, such as a TV and a refrigerator, or medical appliances.

FIG. 14 illustrates an example in which the light-emitting device package 200 manufactured by the manufacturing method according to the embodiment of the inventive concept is applied to a head lamp 3000.

Referring to FIG. 14, the head lamp 3000 used for a vehicle lighting may include a light source 3001, a reflector 3005, and a lens cover 3004. The lens cover 3004 may include a hollow guide 3003 and a lens 3002. The light source 3001 may include the light-emitting device package 100 or the light-emitting devices 120 described above with reference to FIGS. 1, 3, 4, and 7.

The heat lamp 3000 may further include a heat dissipation portion 3012 that discharges heat generated in the light source 3001 to the outside, and the heat dissipation portion 3012 may include a heat sink 3010 and a cooling fan 3011 for efficient heat dissipation. The head lamp 3000 may further include a housing 3009 that fixes and supports the heat dissipation portion 3012 and the reflection unit 3005. The housing may include a body portion 3006, and a central hole 3008 provided at one side such that the heat dissipation portion 3012 is coupled and mounted thereon.

The housing 3009 may include a front hole 3007 provided at the other side integrally connected to the one side and bent in an orthogonal direction, such that the reflection portion 3005 is positioned and fixed at an upper side of the light source 3001. The front side is opened by the reflection portion 3005, and the reflection portion 3005 is fixed to the housing 3009 such that the opened front side corresponds to the front hole 3007. Therefore, light reflected through the reflection portion 3005 may pass through the front hole 3007 and exit to the outside.

While the inventive concept has been particularly shown and described with reference to exemplary embodiments thereof, it will be understood that various changes in form and details may be made therein without departing from the spirit and scope of the following claims.

What is claimed is:

1. A method of manufacturing a light-emitting device package, the method comprising steps of:
preparing a light-emitting device package;
mounting the light-emitting device package on an inspection table;
reflecting, by using a reflection member, leaking blue light among light emitted by the light-emitting device package;
capturing, by using a photographing unit, the light emitted by the light-emitting device package and the leaking blue light and generating an optical image;
detecting, by a controller, the blue light from the optical image;
determining presence or absence of a defect of the light-emitting device package according to the detected blue light; and
displaying the presence or absence of the defect of the light-emitting device package on a display unit.

2. The method of claim 1, wherein the step of preparing the light-emitting device package comprises:
forming a light-emitting device on a substrate;
forming a phosphor layer that covers the light-emitting device; and
forming a lens unit that covers a top surface of the substrate, the light-emitting device, and the phosphor layer.

3. The method of claim 2, wherein the light-emitting device generates blue light, and the generated blue light is emitted as white light through the phosphor layer.

4. The method of claim 1, wherein the inspection table comprises:
a holding table on which the light-emitting device package is mounted; and
a coupling groove portion coupled to one side of a top surface of the light-emitting device package to fix the light-emitting device package.

5. The method of claim 1, wherein the reflection member is inclined at a predetermined angle with respect to a top surface of the inspection table.

6. The method of claim 1, wherein the reflection member is made of a coated alloy capable of reflecting the blue light leaking out from the light-emitting device package.

7. The method of claim 1, wherein the reflection member is disposed adjacent to each side of the light-emitting device package.

8. The method of claim 1, wherein the controller selectively detects blue light having a wavelength of about 400 nm to about 500 nm in the reflected light.

9. The method of claim 1, wherein the light-emitting device package comprises a light-emitting region that emits white light, and
the controller calculates a ratio of a region where blue light is recorded with respect to a region of the entire optical image, except for a region of the optical image corresponding to the light-emitting region, and executes an algorithm of determining a presence or absence of a defect according to a calculation result.

10. The method of claim 9, wherein the light-emitting device package is determined as defective when the ratio of the region where the blue light is recorded with respect to a region of the entire optical image, except for a region where white light emitted from the light-emitting region is recorded, is 7% or more.

11. The method of claim 9, wherein the ratio is displayed on the display unit.

12. A method of manufacturing a light-emitting device package, the method comprising steps of:
preparing a light-emitting device package by forming a phosphor layer on a light-emitting device emitting blue light, wherein the phosphor layer performs conversion to emit white light; and
determining presence or absence of a defect of the light-emitting device package,
wherein the step of determining the presence or absence of the defect of the light-emitting device package comprises:
forming a reflection member surrounding each side of the light-emitting device package;
detecting, by a controller, leaking blue light from light emitted by the light-emitting device package;
calculating a ratio of the leaking blue light with respect to the entire reflected light; and
determining, by the controller, the presence or absence of the defect of the light-emitting device package according to the ratio of the leaking blue light with respect to the entire reflected light.

13. The method of claim 12, wherein the determining of the presence or absence of the defect of the light-emitting device package further comprises displaying the ratio of the leaking blue light on a display unit.

14. The method of claim 12, wherein the step of determining the presence or absence of the defect of the light-emitting device package further comprises:
holding the light-emitting device package on an inspection table; and
fixing the light-emitting device package by coupling one side of a top surface of the light-emitting device package.

15. The method of claim 12, wherein the step of determining the presence or absence of the defect of the light-emitting device package further comprises:
capturing, by using a photographing unit, the reflected light and generating an image; and
transferring, by using the controller, the image.

16. A method of inspecting a defect of a light-emitting device package, the method comprising steps of:
mounting a light-emitting device package on an inspection table;
converting light emitted by the light-emitting device package and blue light leaked from the light-emitting package to an image;
presetting a peripheral region of the image;
determining a ratio of a region of the image, which is converted by the blue light, with respect to the preset peripheral region of the image; and
determining presence or absence of a defect of the light-emitting device package in accordance with whether the determined ratio is equal to and greater than a predetermined ratio.

17. The method of claim 16, further comprising a step of reflecting the blue light leaked from the light-emitting package to a photographing unit used to capture the image.

18. The method of claim 16, further comprising a step of displaying the presence or absence of the defect of the light-emitting device package on a display device.

19. The method of claim 16, wherein the predetermined ratio is equal to 7%.

20. The method of claim 16, wherein the preset peripheral region of the image does not include a center region of the image which is converted by the light emitted by the light-emitting device package.
